(19) United States
(12) Patent Application Publication
(10) Pub. No.: US 2010/0157331 A1
(43) Pub. Date: Jun. 24, 2010

(54) Color Smoothing Mechanism for an Ink Minimizing Profile Making Tool

(76) Inventor: Vladimir Shestak, Boulder, CO (US)

Correspondence Address: InfoPrint Solutions/ Blakely, 1279 Oakmead Parkway, Sunnyvale, CA, 94085-4040, US

(21) Appl. No.: 12/342,727

(22) Filed: Dec. 23, 2008

(51) Int. Cl. H04N 1/60; G03F 3/08

(52) U.S. Cl. 358/1.9; 358/518

(57) ABSTRACT

An International Color Consortium (ICC) profile making tool includes a regression module to establish a dependency between a profile connection space (PCS) and a device color space, an optimization module to generate a first output profile based on an ink minimization mode and a second output profile based on a high accuracy mode and a smoothing module to prevent fluctuating transitions between colors occurring in the first output profile.

### FIELD OF THE INVENTION

This invention relates generally to the field of printing systems. More particularly, the invention relates to managing and controlling ink usage in a color printing system.

### BACKGROUND

Growth in color management has resulted in an increase in software packages that are used to generate International Color Consortium (ICC) profiles. ICC profiles describe color attributes of a particular device or viewing requirement by defining a mapping between a source or target color space and a profile connection space (PCS), which is either CIELAB (L*a*b*) or CIEXYZ.

An ICC profile also plays an important role in ink consumption at a printer driver, or third party software, since the profile provides the means of determining CMYK intensities for each point in a given image. The minimization of ink usage at printers has been an important and challenging problem, which has had a significant economic impact. However, a minimization of ink usage may result in a contouring effect on images due to fluctuating transitions between adjacent colors.

Therefore, what is desired is an ICC profile mechanism that eliminates fluctuations between color channels.

### SUMMARY

In one embodiment, an ICC profile tool is disclosed. An International Color Consortium (ICC) profile tool includes a regression module to establish a dependency between a profile connection space (PCS) and a device color space, an optimization module to generate a first output profile based on an ink minimization mode and a second output profile based on a high accuracy mode and a smoothing module to prevent fluctuating transitions between colors occurring in the first output profile.

In another embodiment, a method is disclosed. The method includes performing a regression method to establish a dependency between a profile connection space (PCS) and a device color space, performing an optimization method to generate a first ICC profile based on an ink minimization mode and a second ICC profile based on a high accuracy mode and performing a smoothing method to prevent fluctuating transitions between colors occurring in the first ICC profile

A further discloses an article of manufacture comprising a computer-readable medium having associated data, wherein the data, when accessed, results in a machine performing operations comprising performing a regression method to establish a dependency between a profile connection space (PCS) and a device color space and performing an optimization method to generate a first International Color Consortium (ICC) profile based on an ink minimization mode and a second ICC profile based on a high accuracy mode and performing a smoothing method to prevent fluctuating transitions between colors occurring in the first ICC profile.

### BRIEF DESCRIPTION OF THE DRAWINGS

A better understanding of the present invention can be obtained from the following detailed description in conjunction with the following drawings, in which:

FIG. 1 illustrates one embodiment of an ICC profile tool;

FIG. 2 illustrates one embodiment of a regression model;

FIG. 3 illustrates one embodiment of an optimization module;

FIG. 4A illustrates a mapping of a node from the CMYK space to the L*a*b space;

FIG. 4B illustrates reproduced colors in the L*a*b space

FIG. 5A illustrate one embodiment of smoothing color values;

FIGS. 5B illustrates one embodiment of smoothing color values; and

FIG. 6 illustrates one embodiment of a computer system.

### DETAILED DESCRIPTION

An ICC profile tool with smoothing techniques is described. In the following description, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form to avoid obscuring the underlying principles of the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

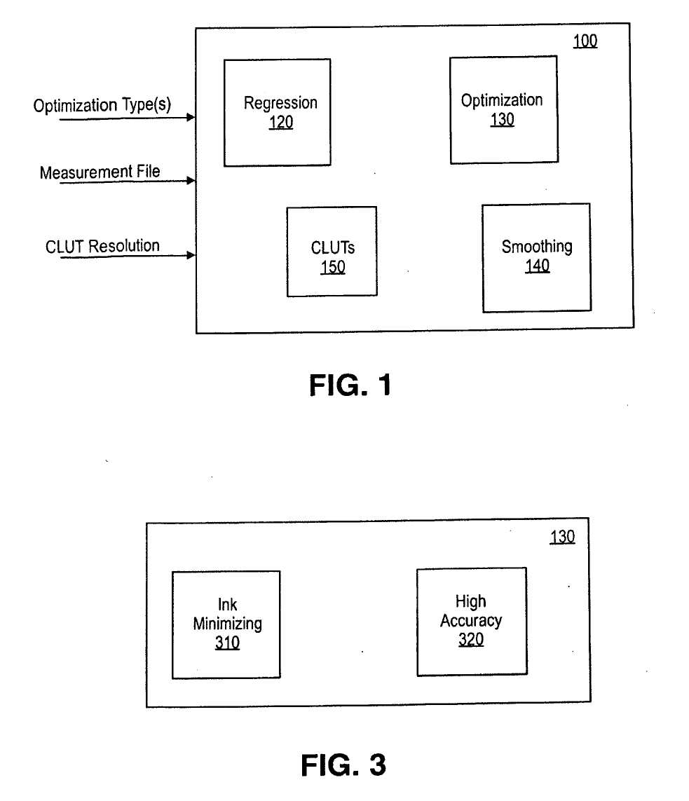

FIG. 1 illustrates one embodiment of an ICC profile tool 100. Profile tool 100 is a tool for making, editing and assessing ICC profiles. According to one embodiment, ICC profile tool 100 generates an ICC output profile with respect to a set of parameter values that are passed to a point operation optimization algorithm.

In such an embodiment, a multitude of different ICC profiles, depending on a parameter setup, may be produced for a given printer that addresses a trade-off between print quality and amount of ink required. In a further embodiment, the output profile may be applied to any ink jet or EP printer.

According to one embodiment, tool 100 receives as input from a user: a measurement file, type of optimization and color lookup table (CLUT) resolution. CLUT resolution determines how many evenly distributed points will be used to represent a grid that spans an entire device independent color space (e.g., typical values 9, 25, or 33).

The measurement file may be a standard print charts, e.g., ECI2002V, printed on a target printer and measured in XYZ or the CIE 1976 L*a*b color spaces. In one embodiment, the measurement file is obtained by a particular printer printing out the chart, which is measured using a spectrophotometer. As a result, the set of points (called sample set) in L*a*b is obtained with known responses in the device color space.

The type of optimization includes an ink minimizing mode and a high accuracy mode. The ink minimizing mode enables a user to establish a limit as to how much a reproduced color (e.g., the result of ink minimization) can deviate from the requested color in the device independent color space. In one embodiment, a user specifies a level of print quality that is acceptable in the ink minimizing mode. The high accuracy mode ensures that color error will be minimized between the requested and reproduced color regardless of the amount of ink consumed. In one embodiment each mode, an ICC profile is generated that includes an associated set of CLUTs 150 that can be used in the color management system of a given printer to implement the respective mode.

According to one embodiment, tool 100 includes regression module 120, optimization module 130 and smoothing module 140. The regression module performs a method that establishes dependency between L*a*b and device color space (e.g., CMYK).

### Regression Model

As a first step, regression module 120 retrieves the sample set derived from the measurement file. In one embodiment, the above-described functional dependency between L*a*b* and CMYK is established using polynomials. For example for the first degree polynomial degree, the functional dependency, denoted as F(CMY K)·LAB, can be written as:

$$[ \begin{matrix}b \\ a \\ L\end{matrix} ] = [ \begin{matrix}{β}_{const 1} & {β}_{11} & {β}_{12} & {β}_{13} & {β}_{14} ] \\ {β}_{const 2} & {β}_{21} & {β}_{22} & {β}_{23} & {β}_{24} \\ {β}_{const 3} & {β}_{31} & {β}_{32} & {β}_{33} & {β}_{34}\end{matrix} ] \times [ \begin{matrix}C \\ M \\ Y \\ K\end{matrix} ]$$

where (3×5) β matrix contains the regression coefficients.

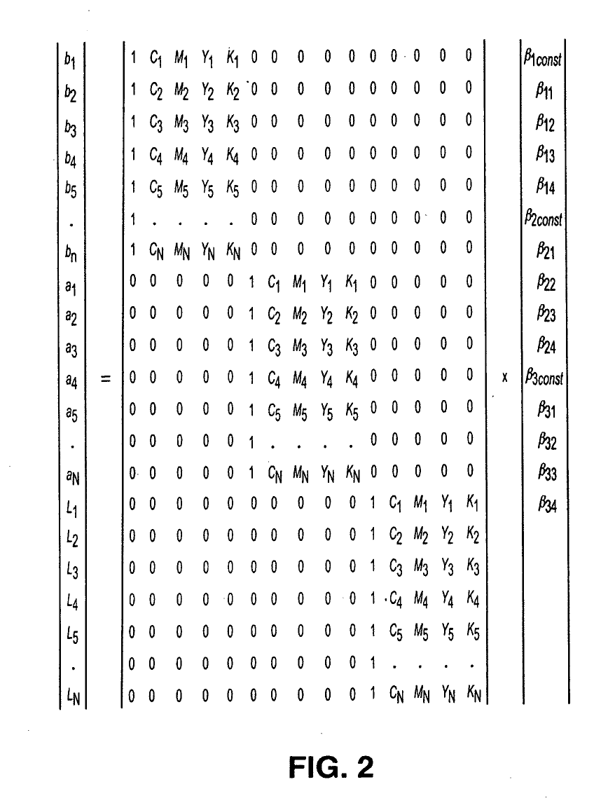

The computation of these coefficients is based on the closed form solution of the least square error minimization for the subset of sample points. This subset of sample points is selected individually for each node in the constructed BtoA CLUT. This concept of locality is very important as F(CMY K)→LAB may vary from one region of printer's gamut to another. Suppose that the given subset of sample points is composed of N points, each point i, 1≦i≦N is specified by Liaibi coordinates in Lab space and CiMiYiKi in CMYK space. The regression model for the first degree polynomial is shown in FIG. 2. Let \hat{b}ᵢ, âᵢ, and \hat{L}ᵢ denote the b, a and L components of the right hand side vector in FIG. 2, computed when β coefficients are found.

The least square regression implies that β coefficients are determined such that

$$\sqrt{{\sum }_{i = 1}^{N} [ {( {b}_{i} - \hat{{b}_{i}} )}^{2} + {\sum }_{i = 1}^{N} {( {a}_{i} - \hat{{a}_{i}} )}^{2} + {\sum }_{i = 1}^{N} {( {L}_{i} - \hat{{L}_{i}} )}^{2} ]} \qquad ( Equation 1 )$$

is minimized. It is very important to note that this is a least squares optimization of Euclidean distances between actual sample points in Lab space and corresponding mappings from CMYK space. To see this, Equation 1 can be written as:

$$\sqrt{{\sum }_{i = 1}^{N} [ {( {b}_{i} - \hat{{b}_{i}} )}^{2} + {\sum }_{i = 1}^{N} {( {a}_{i} - \hat{{a}_{i}} )}^{2} + {\sum }_{i = 1}^{N} {( {L}_{i} - \hat{{L}_{i}} )}^{2} ]} = \sqrt{{\sum }_{i = 1}^{N} {( \sqrt{{( {b}_{i} - \hat{{b}_{i}} )}^{2} + {\sum }_{i = 1}^{N} {( {a}_{i} - \hat{{a}_{i}} )}^{2} + {\sum }_{i = 1}^{N} {( {L}_{i} - \hat{{L}_{i}} )}^{2}} )}^{2}} = \sqrt{{\sum }_{i = 1}^{N} {Δ}_{i}^{2}} \qquad ( Equation 2 )$$

By these means, our regression model resolves the common pitfall in color science based on the fact that the least squares optimization is applied to find β coefficients separately for L, a and b. As a result, that approach does not minimize

$$\sqrt{{\sum }_{i = 1}^{N} {Δ}_{1}^{2}} .$$

Let V (C M Y K) be a vector formed with all terms of k-degree polynomial constructed from the elements of [C M Y K] vector. In general, the F(CMY K)→LAB can be expressed as [L a b]=[3×length of V(C M Y K)] β matrix×V(C M Y K). In one embodiment, first degree polynomials were used in profile tool 100 for subsets with a small number of sample points, second degree—for other subsets.

### Optimization Setup

Referring back to FIG. 1, once the regression method has been performed at regression module 120 control is forwarded to optimization module 130. FIG. 3 illustrates one embodiment of an optimization module 130. Optimization module 130 includes two modules to perform optimization setups for non-linear optimization. These modules include ink minimizing module 310 and high accuracy module 320. However, in some embodiments, an ink limit may be applied at both modules.

Let [lab] denote a node in the constructed B to A CLUT. Once the local relation F(CMY K)→LAB is established node for node [lab], the optimization problem can be formulated mathematically at ink saving module 310 and high accuracy module 320. The ink saving mode is formulated as:

minimize C+M+Y+K

subject to
   ||F(CMY K)−[lab]||≦Δₗᵢₘᵢₜ;
C+M+Y+K≦Ωₗᵢₘᵢₜ;
0≦C≦100; 0≦M≦100; 0≦Y≦100; 0≦K≦100.

while the high accuracy mode is formulated as:

minimize ||F(CMY K)−[lab]||

subject to
C+M+Y+K≦Ωₗᵢₘᵢₜ;
0≦C≦100; 0≦M≦100; 0≦Y≦100; 0≦K≦100,
   where Δₗᵢₘᵢₜ and Ωₗᵢₘᵢₜ specify the maximum deviation from node [lab] in L*a*b* space and maximum ink coverage, respectively.

In these formulations, the non-linear element ||F(CMY K)−[lab]||provides a qualitative measure of deviation from node [lab]. In one embodiment, an additional constraint limiting ink coverage is provided to the set of constraints to prevent paper distortion failures (e.g., curl, cockle, and tearing). In a further embodiment, the formulations can be modified to address the specific details of optimization. For example C+M+Y+K can be replaced with a weighted sum p_{c}×C+pₘ×M+pₖ×K, where each coefficient p represents a cost of the corresponding ink.

According to one embodiment, a local optimal solution can be found for the non-linear constrained optimization modes in a finite number of iterations by applying mathematical procedures based on the projected gradient methods, penalty function, etc. In another embodiment, commercially available third party optimization packages, e.g., Matlab, Lingo, can be used for this purpose. In addition, a variety of global optimization iterative heuristics, e.g., Genetic Algorithm, Simulated Annealing, can be adapted for this purpose.

### Smoothing

The result of the above-described progression and optimization processes produce ICC profiles with generally correct color representations. However, the ink minimization profiles produce transitions between adjacent colors that are not smooth, leading to contouring effects on images. These contouring effects are a result of the constrained-optimization search that determines a CMYK combination for each node in the Lab space such that the cost of ink to reproduce this node is minimized.

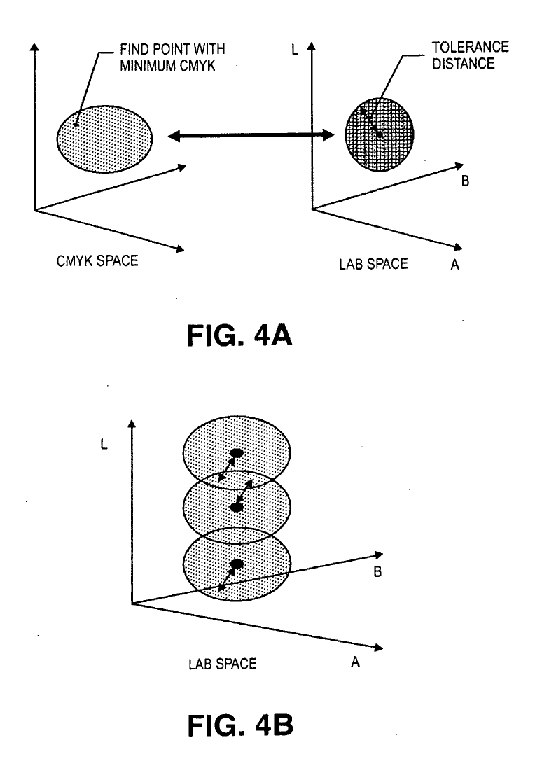

As shown in FIG. 4A, a reproduced L*a*b color does not need be exact (e.g., a deviation radius is specified for the optimizer), and optimization process is independent from one Lab node to another. As a result, some of the adjacent colors demonstrate a lack of consistency, as shown in FIG. 4B.

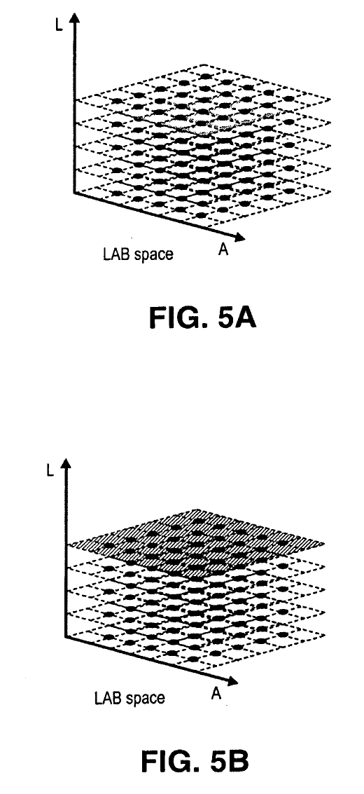

Referring again to FIG. 1, smoothing module 140 is implemented to perform smoothing techniques to overcome the problem of fluctuating transitions between colors. According to one embodiment, values for each color channel (e.g., C, M, Y, and K) in each BtoA CLUT 150 is first smoothed in the L* direction. In such an embodiment, a robust smoothing technique (e.g., rlowess, rloess) is applied to a set of L* values formed for a fixed point on a ab plane (e.g., an L*-column of the CLUT 150 grid in the L*a*b space). FIG. 5A illustrates one embodiment of a one dimensional smoothing of a CLUT 150 for every L column L*a*b space.

In one embodiment, the smoothing technique assign lower weights to outliers in the regression and zero weights if data is outside a predetermined threshold (e.g., six mean absolute deviations). This process enables the avoidance of contouring effects and the achievement of enhanced color transitions in the L* direction.

In a further embodiment, smoothing module 140 performs an additional process involving a two-dimensional robust smoothing of each color channel on the ab plane for a fixed L* point in each CLUT 150. FIG. 5A illustrates one embodiment of a two-dimensional smoothing applied for every ab-plane in the L*a*b space. The two-dimensional smoothing process repairs hue fluctuations, which are the most noticeable and unpleasant problems in color.

### System

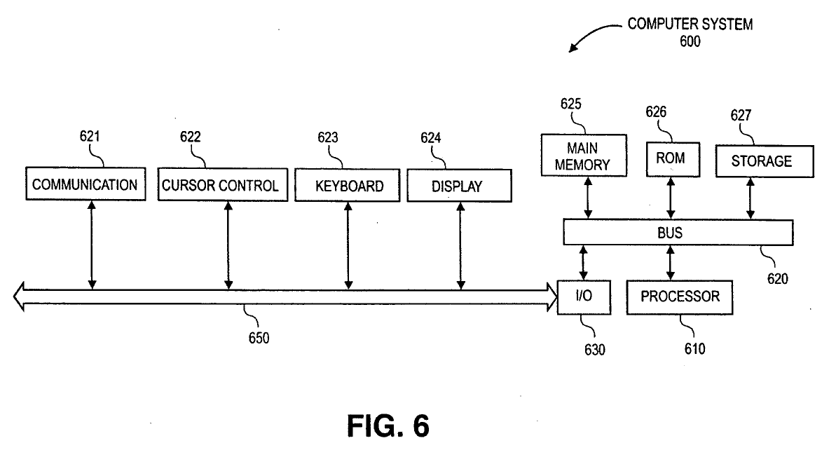

FIG. 6 illustrates a computer system 600 on which ICC profile tool 100 may be implemented. Computer system 600 includes a system bus 620 for communicating information, and a processor 610 coupled to bus 620 for processing information. According to one embodiment, processor 610 is implemented using one of the multitudes of ARM™ microprocessors. Nevertheless one of ordinary skill in the art will appreciate that other processors may be used.

Computer system 600 further comprises a random access memory (RAM) or other dynamic storage device 625 (referred to herein as main memory), coupled to bus 620 for storing information and instructions to be executed by processor 610. Main memory 625 also may be used for storing temporary variables or other intermediate information during execution of instructions by processor 610. Computer system 600 also may include a read only memory (ROM) and or other static storage device 626 coupled to bus 620 for storing static information and instructions used by processor 610.

A data storage device 625 such as a magnetic disk or optical disc and its corresponding drive may also be coupled to computer system 600 for storing information and instructions. Computer system 600 can also be coupled to a second I/O bus 650 via an I/O interface 630. A plurality of I/O devices may be coupled to I/O bus 650, including a display device 624, an input device (e.g., an alphanumeric input device 623 and or a cursor control device 622). The communication device 621 is for accessing other computers (servers or clients). The communication device 621 may comprise a modem, a network interface card, or other well-known interface device, such as those used for coupling to Ethernet, token ring, or other types of networks.

Embodiments of the invention may include various steps as set forth above. The steps may be embodied in machine-executable instructions. The instructions can be used to cause a general-purpose or special-purpose processor to perform certain steps. Alternatively, these steps may be performed by specific hardware components that contain hardwired logic for performing the steps, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

The above-described smoothing mechanism limits contouring effects on images caused during ink minimization of profiles.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as essential to the invention.

What is claimed is:

1. An International Color Consortium (ICC) profile tool comprising:
a regression module to establish a dependency between a profile connection space (PCS) and a device color space;
an optimization module to generate a first output profile based on an ink minimization mode and a second output profile based on a high accuracy mode; and
a smoothing module to prevent fluctuating transitions between colors occurring in the first output profile.

2. The profile tool of claim 1 wherein the first output profile comprises a first set of color lookup tables (CLUTs) and the second output profile comprises a second set of CLUTs.

3. The profile tool of claim 2 wherein the smoothing module smoothes values for each color in the first set of CLUTs in a L* direction.

4. The profile tool of claim 3 wherein the smoothing module smoothes values by performing a rlowess smoothing technique to a set of L* values formed for a fixed point on a ab plane in the first set of CLUTs.

5. The profile tool of claim 3 wherein the smoothing module smoothes values by performing a rloess smoothing technique to a set of L* values formed for a fixed point on a ab plane in the first set of CLUTs.

6. The profile tool of claim 3 wherein the smoothing module smoothes values by assigning lower weights to outliers in a regression and zero weights if data is outside a predetermined threshold.

7. The profile tool of claim 3 wherein the smoothing module further smoothes each color channel on a ab plane for a fixed L* point in the first set of CLUTs in a L* direction to repair hue fluctuations.

8. A method comprising:
performing a regression method to establish a dependency between a profile connection space (PCS) and a device color space; and
performing an optimization method to generate a first International Color Consortium (ICC) profile based on an ink minimization mode and a second ICC profile based on a high accuracy mode; and
performing a smoothing method to prevent fluctuating transitions between colors occurring in the first ICC profile.

9. The method of claim 8 wherein the first ICC profile comprises a first set of color lookup tables (CLUTs) and the second ICC profile comprises a second set of CLUTs.

10. The method of claim 9 wherein the smoothing method comprises smoothing values for each color in the first set of CLUTs in a L* direction.

11. The method of claim 10 wherein smoothing the values comprises performing a rlowess smoothing technique to a set of L* values formed for a fixed point on a ab plane in the first set of CLUTs.

12. The method of claim 10 wherein smoothing the values comprises performing a rloess smoothing technique to a set of L* values formed for a fixed point on a ab plane in the first set of CLUTs.

13. The method of claim 10 wherein smoothing the values comprises assigning lower weights to outliers in a regression and zero weights if data is outside a predetermined threshold.

14. The method of claim 10 wherein the smoothing method further comprises smoothing each color channel on a ab plane for a fixed L* point in the first set of CLUTs in a L* direction to repair hue fluctuations.

15. An article of manufacture comprising a computer-readable medium having associated data, wherein the data, when accessed, results in a machine performing operations comprising:
performing a regression method to establish a dependency between a profile connection space (PCS) and a device color space; and
performing an optimization method to generate a first International Color Consortium (ICC) profile based on an ink minimization mode and a second ICC profile based on a high accuracy mode; and
performing a smoothing method to prevent fluctuating transitions between colors occurring in the first ICC profile.

16. The article of manufacture of claim 15 wherein the first ICC profile comprises a first set of color lookup tables (CLUTs) and the second ICC profile comprises a second set of CLUTs.

17. The article of manufacture of claim 16 wherein the smoothing method comprises smoothing values for each color in the first set of CLUTs in a L*

18. The article of manufacture of claim 17 wherein smoothing the values comprises performing a rlowess smoothing technique to a set of L* values formed for a fixed point on a ab plane in the first set of CLUTs.

19. The article of manufacture of claim 17 wherein smoothing the values comprises performing a rloess smoothing technique to a set of L* values formed for a fixed point on a ab plane in the first set of CLUTs.

20. The article of manufacture of claim 17 wherein the smoothing method further comprises smoothing each color channel on a ab plane for a fixed L* point in the first set of CLUTs in a L* direction to repair hue fluctuations.
